(19) United States
(12) Patent Application Publication
(10) Pub. No.: US 2024/0429242 A1
(43) Pub. Date: Dec. 26, 2024

(54) THIN FILM TRANSISTOR SUBSTRATE AND METHOD OF MANUFATURING THE SAME AND DISPLAY DEVICE USING THE SAME

(71) Applicant: LG Display Co., Ltd., Seoul (KR)

(72) Inventors: Hyeonjoo SEUL, Paju-si (KR); Jaeyoon PARK, Paju-si (KR); Jinwon JUNG, Paju-si (KR); Dongyeon KANG, Paju-si (KR)

(73) Assignee: LG Display Co., Ltd., Seoul (KR)

(21) Appl. No.: 18/749,931

(22) Filed: Jun. 21, 2024

(30) Foreign Application Priority Data
Jun. 26, 2023 (KR) 10-2023-0081683

(51) Int. Cl. H01L 27/12; H01L 29/417

(52) U.S. Cl. CPC H01L 27/1225; H01L 27/127; H01L 29/41733

(57) ABSTRACT

A thin film transistor substrate for a display device can include a light blocking layer disposed on a substrate, an active layer overlapping with the light blocking layer, a first lower hole penetrating through the active layer, a gate electrode overlapping with the active layer, a source electrode penetrating through the active layer and contacting with the light blocking layer, an insulating layer disposed on the active layer, and a first upper hole penetrating through the insulating layer. Also, the source electrode includes a first lower electrode disposed in the first lower hole and a first upper electrode disposed in the first upper hole, in which a width of the first upper electrode is greater than a width of the first lower electrode.

### CROSS-REFERENCE TO RELATED APPLICATIONS

This application claims priority to Korean Patent Application No. 10-2023-0081683 filed in the Republic of Korea, on Jun. 26, 2023, the entirety of which is hereby incorporated by reference into the present application as if fully set forth herein.

### BACKGROUND

### Technical Field

The present disclosure relates to a thin film transistor substrate, a method of manufacturing the same, and a display device using the same.

### Description of the Related Art

Since thin film transistors can be manufactured on glass or plastic substrates, they are widely used as switching or driving elements of display devices such as liquid crystal display devices or organic light emitting devices.

Based on the material constituting the active layer, thin film transistors can be divided into amorphous silicon thin film transistors in which amorphous silicon is used as an active layer, polycrystalline silicon thin film transistors in which polycrystalline silicon is used as an active layer, and oxide semiconductor thin film transistors in which oxide semiconductor is used as active layers.

Among them, oxide semiconductor thin film transistors (Oxide semiconductor TFTs) have the advantage of being able to easily obtain desired physical properties because they have high mobility and can have a large resistance change depending on the oxygen content. In addition, the manufacturing cost is low because the oxide constituting the active layer can be formed at a relatively low temperature in the manufacturing process of the oxide semiconductor thin film transistor. Due to the nature of the oxide, since the oxide semiconductor is transparent, it is also advantageous to implement a transparent display device.

Recently, in order to implement a high-resolution display device, the size of pixels has been made even smaller. In order to implement such a high-resolution display device, it is desirable to minimize or reduce the size of the thin film transistor disposed in the pixel. Meanwhile, in order to express the gray scale of the driving thin film transistor for driving the pixel, a method of electrically connecting the active layer, the source electrode, and the light blocking layer to increase the size of the capacitor may be used, but in this situation, there are often issues regarding the ability to secure enough space for implementing a high-resolution display device due to the size of the source electrode for connecting the active layer and the light blocking layer.

Accordingly, there is a need for a thin film transistor having a configuration that can better reduce the footprint size while still being able to express good gray scale levels, and provide more design freedom for implementing higher resolutions.

### SUMMARY OF THE DISCLOSURE

The present disclosure provides a thin film transistor substrate with a thin film transistor can better express gray scale by connecting a source electrode, an active layer, and a light blocking layer through a lower hole disposed in the active layer of the thin film transistor, and a display device including the same.

In accordance with an aspect of the present disclosure, the above and other objects can be accomplished by the provision of a thin film transistor substrate including a substrate, a light blocking layer disposed on the substrate, an active layer disposed on the light blocking layer and having a lower hole on one side, a gate electrode disposed on the active layer, a source electrode disposed on the gate electrode and electrically connected to the light blocking layer, and an insulating layer disposed between the active layer and the source electrode and including a upper hole, in which the source electrode includes a lower electrode disposed in the lower hole and an upper electrode disposed in the upper hole, and an area of a lower surface of the upper electrode is larger than an area of an upper surface of the lower electrode.

And the above and other objects can be accomplished by the provision of a method of manufacturing a thin film transistor substrate including a step of forming a light blocking layer on the substrate, a step of forming an active layer on the light blocking layer, a step of forming an active hole on one side of the active layer, a step of forming a gate insulating layer on the active layer in which the active hole is formed, a step of forming a gate electrode on the gate insulating layer, a step of forming an interlayer insulating layer on the gate electrode, a step of forming an upper hole in the gate insulating layer and the interlayer insulating layer, a step of forming a lower hole exposing a portion of the light blocking layer by extending the active hole and a step of forming a source electrode inside the lower hole and inside the upper hole.

And the above and other objects can be accomplished by the provision of a display device including a substrate including a display area and non-display area, a first thin film transistor disposed on the substrate and a second thin film transistor having a structure different from that of the first thin film transistor, in which The first thin film transistor includes a first light blocking layer, a first active layer disposed on the first light blocking layer and having a lower hole disposed on one side thereof, a first gate electrode disposed on the first active layer, a first source electrode disposed on the first gate electrode and electrically connected to the first active layer and the first light blocking layer and an insulating layer disposed between the first active layer and the first source electrode and having an upper hole, the first source electrode includes a lower electrode disposed in the lower hole and an upper electrode disposed in the upper hole, the first active layer and the first light blocking layer are electrically connected through the lower electrode and an area of a lower surface of the upper electrode is larger than an area of an upper surface of the lower electrode.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a thin film transistor substrate according to an embodiment of the present disclosure.

FIG. 2A is a cross-sectional view of a thin film transistor substrate according to an embodiment of the present disclosure. In this situation, the cross-sectional view of FIG. 2A corresponds to the cross-section taken along line I-I′ of FIG. 1 according to an embodiment of the present disclosure.

FIG. 2B is a cross-sectional view of a thin film transistor substrate according to another embodiment of the present disclosure. In this situation, the cross-sectional view of FIG. 2B corresponds to the cross-section taken along line I-I′ of FIG. 1.

FIG. 3 is a plan view of a thin film transistor substrate according to another embodiment of the present disclosure.

FIG. 4 is a cross-sectional view of a thin film transistor substrate according to another embodiment of the present disclosure. In this situation, the cross-sectional view of FIG. 4 corresponds to the cross-section taken along line II-II′ of FIG. 3.

FIG. 5 is a plan view of a thin film transistor substrate according to another embodiment of the present disclosure.

FIG. 6 is a cross-sectional view of a thin film transistor substrate according to another embodiment of the present disclosure. In this situation, the cross-sectional view of FIG. 6 corresponds to the cross-section taken along line III-III′ of FIG. 5.

FIG. 7 is a plan view of a thin film transistor substrate according to another embodiment of the present disclosure.

FIG. 8 is a cross-sectional view of a thin film transistor substrate according to another embodiment of the present disclosure. In this situation, the cross-sectional view of FIG. 8 corresponds to the cross-section taken along line IV-IV′ of FIG. 7.

FIG. 9 is a plan view of a thin film transistor substrate according to another embodiment of the present disclosure.

FIG. 10 is a cross-sectional view of a thin film transistor substrate according to another embodiment of the present disclosure. In this situation, the cross-sectional view of FIG. 10 corresponds to the cross-section of V-V′ of FIG. 9.

FIG. 11 is a plan view of a thin film transistor substrate according to another embodiment of the present disclosure.

FIG. 12 is a cross-sectional view of a thin film transistor substrate according to another embodiment of the present disclosure. In this situation, the cross-sectional view of FIG. 12 corresponds to the cross-section of VI-VI′ of FIG. 11.

FIG. 13 is a cross-sectional view of a thin film transistor substrate according to another embodiment of the present disclosure.

FIG. 14 is a cross-sectional view of a thin film transistor substrate according to another embodiment of the present disclosure.

FIGS. 15A to 15E are cross-sectional views illustrating a method of forming a thin film transistor substrate according to an embodiment of the present disclosure.

FIG. 16 is a cross-sectional view of a display device including a thin film transistor substrate according to another embodiment of the present disclosure.

FIG. 17 is a schematic view of a display device according to an embodiment of the present disclosure.

FIG. 18 is a circuit diagram of a pixel included in a display device according to an embodiment of the present disclosure.

FIG. 19 is a circuit diagram of a pixel included in a display device according to another embodiment of the present disclosure.

FIG. 20 is a circuit diagram of a pixel included in a display device according to another embodiment of the present disclosure.

### DETAILED DESCRIPTION OF THE EMBODIMENTS

Advantages and features of the present disclosure, and implementation methods thereof will be clarified through the following embodiments, described with reference to the accompanying drawings. The present disclosure can, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the situation in which “comprise,” “have,” and “include” described in the present specification are used, another part can also be present unless “only” is used. The terms in a singular form can include plural forms unless noted to the contrary.

In construing an element, the element is construed as including an error region although there is no explicit description thereof.

In describing a positional relationship, for example, when the positional order is described as “on,” “above,” “below,” “beneath,” and “next,” the situation of no contact therebetween can be included, unless “just” or “direct” is used.

If it is mentioned that a first element is positioned “on” a second element, it does not mean that the first element has to be positioned above the second element in the figure. The upper part and the lower part of an object concerned can be changed depending on the orientation of the object. Consequently, the situation in which a first element is positioned “on” a second element includes the situation in which the first element is positioned “below” the second element as well as the situation in which the first element is positioned “above” the second element in the figure or in an actual configuration.

In describing a temporal relationship, for example, when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other, and can be variously inter-operated with each other and driven technically The embodiments of the present disclosure can be carried out independently from each other, or can be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode can be the drain electrode, and the drain electrode can be the source electrode. Also, the source electrode in any one embodiment of the present disclosure can be the drain electrode in another embodiment of the present disclosure, and the drain electrode in any one embodiment of the present disclosure can be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region can be a source electrode, and a drain region can be a drain electrode. Also, a source region can be a drain electrode, and a drain region can be a source electrode.

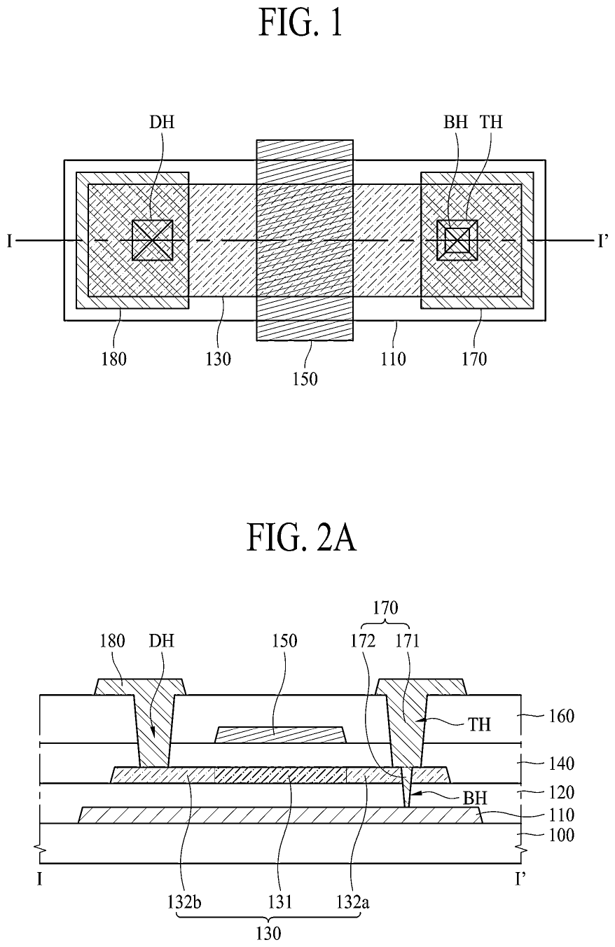

FIG. 1 is a plan view of a thin film transistor substrate according to an embodiment of the present disclosure.

As shown in FIG. 1, the thin film transistor substrate according to an embodiment of the present disclosure can include a light blocking layer 110, an active layer 130, a gate electrode 150, a source electrode 170, and a drain electrode 180.

The light blocking layer 110 and the active layer 130 can extend in a first direction, e.g., a horizontal direction, and the gate electrode 150 can extend in a second direction, e.g., a vertical direction. In this situation, the first direction and the second direction can be orthogonal to each other.

A drain hole DH can be disposed in one side of the active layer 130, e.g., a left side thereof, and an upper hole TH (e.g., top hole) and a lower hole BH (e.g., bottom hole) can be disposed in another side of the active layer 130, e.g., a right side thereof. In this situation, the lower hole BH and the upper hole TH can overlap with each other or be in communication with each other.

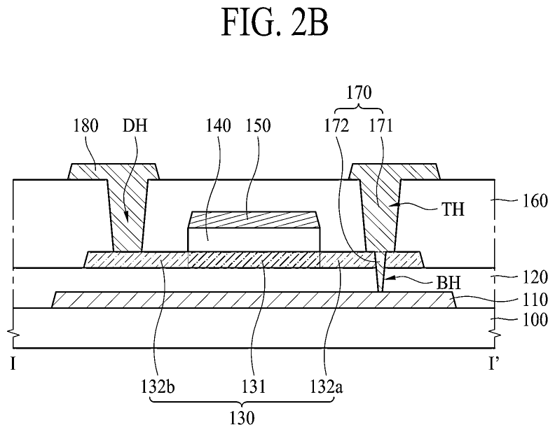

The one side of the active layer 130 can be electrically connected to the drain electrode 180 through the drain hole DH, the another side of the active layer 130 can be electrically connected to the light blocking layer 110 through the lower hole BH, and the another side of the active layer 130 can be electrically connected to the source electrode 170 through the upper hole TH. In this situation, the light blocking layer 110, the active layer 130, and the source electrode 170 can be electrically connected through the upper hole TH and the lower hole BH, thereby facilitating the gray scale expression of the thin film transistor substrate according to an embodiment of the present disclosure, which will be described in detail in FIG. 2A.

FIG. 2A is a cross-sectional view of a thin film transistor substrate according to an embodiment of the present disclosure. In this situation, the cross-sectional view of FIG. 2A corresponds to the cross-section taken along line I-I′ of FIG. 1.

As shown in FIG. 2A, the thin film transistor substrate according to an embodiment of the present disclosure can include a substrate 100, a light blocking layer 110, a buffer layer 120, an active layer 130, a gate insulating layer 140, a gate electrode 150, an interlayer insulating layer 160, a source electrode 170, and a drain electrode 180.

The substrate 100 can be made of glass or plastic. In particular, the substrate 100 can be made of transparent plastic having flexible characteristics, e.g., polyimide. When the polyimide is used as the substrate 100, considering that a high-temperature deposition process is performed on the substrate 100, heat-resistant polyimide capable of withstanding high temperature can be used.

The light blocking layer 110 can be disposed on the substrate 100. The light blocking layer 110 can include a metal or a metal oxide, and can be formed of one metal layer or a metal oxide layer, or can be formed of two or more metal layers or metal oxide layers.

The light blocking layer 110 is disposed under the active layer 130 and overlaps the active layer 130, thereby preventing light introduced from the outside of the thin film transistor substrate from being introduced into the active layer 130 and preventing potential damage to the active layer 130. Specifically, the light blocking layer 110 can prevent external light from being introduced into the channel part 131 of the active layer 130. Meanwhile, a separate insulating layer can be additionally disposed between the light blocking layer 110 and the substrate 100.

The buffer layer 120 is formed on the substrate 100 and the light blocking layer 110. The buffer layer 120 can protect the active layer 130 by blocking air and moisture. The buffer layer 120 can be made of an inorganic insulating material such as silicon oxide, silicon nitride, or metal oxide, but is not limited thereto and can be made of an organic insulating material. The buffer layer 120 can be formed of a single layer or a plurality of layers.

The active layer 130 can be disposed on the buffer layer 120.

The active layer 130 can include a semiconductor material, e.g., an oxide semiconductor material. The oxide semiconductor material can include at least one of, e.g., an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material.

In this situation, the active layer 130, preferably, can include at least one of an IZO (InZnO)-based oxide semiconductor material, an IGZO (InGaZnO)-based oxide semiconductor material, an IZTO (InZnSnO)-based oxide semiconductor material, and a ZnO-based oxide semiconductor material. When the active layer 130 is formed to include the above-described material, a lower hole BH can be more easily formed in one side of the active layer 130.

The active layer 130 includes a channel part 131, a first connection part 132a connected to one side of the channel part 131, and a second connection part 132b connected to another side of the channel part 131. The first connection part 132a and the second connection part 132b can have conductive characteristics by a conducting process of ion doping or plasma treatment on a semiconductor material using the gate electrode 150 as a mask.

The conducting process can be defined as a process of imparting conductive characteristics to an oxide semiconductor material. The oxide semiconductor material in which the conducting process has been performed can have conductive characteristics. The conducting process can include, e.g., a doping process using dopant ions and a plasma process of applying plasma to become a conductor. Through the conducting process, a partial region of the active layer 130 can be conductive to have conductive characteristics. In this situation, the first connection part 132a and the second connection part 132b can be conductive by the conducting process to have conductive characteristics, and the first connection part 132a and the second connection part 132b can have better conductivity than the channel part 131, and each can serve as a wiring or source/drain electrode.

A lower hole BH can be disposed at one side of the active layer 130. Specifically, a region of one side of the active layer 130 can be patterned to form the lower hole BH.

The lower hole BH can be disposed in the first connection part 132a of the active layer 130. The lower hole BH is formed by patterning a partial area of the active layer 130 and a partial area of the buffer layer 120, and the lower hole BH can expose a portion of the upper surface of the light blocking layer 110 provided under the active layer 130. By forming the lower hole BH, the source electrode 170 can penetrate the lower hole BH to connect the first connection part 132a of the active layer 130 with the light blocking layer 110 electrically.

The gate insulating layer 140 can be disposed on the active layer 130. In detail, the gate insulating layer 140 can be disposed on the entire surface of the substrate 100, and can be disposed on the active layer 130 and the buffer layer 120, but embodiments are not limited thereto (e.g., see FIG. 2B). As a result, the active layer 130 can be surrounded by the buffer layer 120 and the gate insulating layer 140.

An upper hole TH and a drain hole DH can be disposed in the gate insulating layer 140.

The gate insulating layer 140 can include a silicon nitride layer SiNx or a silicon oxide layer SiOx, but is not limited thereto. The gate insulating layer 140 can be formed of a single layer or a plurality of layers including an inorganic insulating material and/or an organic insulating material.

The gate electrode 150 can be disposed on the gate insulating layer 140. The gate electrode 150 can be disposed on the active layer 130. Specifically, the gate electrode 150 can overlap the channel part 131 of the active layer 130.

The gate electrode 150 can include at least one of an aluminum-based metal such as aluminum Al or an aluminum alloy, a silver-based metal such as silver Ag or a silver alloy, a copper-based metal such as copper Cu or a copper alloy, a molybdenum-based metal such as molybdenum Mo or a molybdenum alloy, chromium Cr, tantalum Ta, neodymium Nd, and titanium Ti. The gate electrode 150 can have a structure including one metal layer or a multilayer structure including at least two metal layers each having different physical properties.

The interlayer insulating layer 160 can insulate the gate electrode 150 from the source electrode 170, and further insulate the gate electrode 150 from the drain electrode 180. The interlayer insulating layer 160 can be formed of a single layer or a plurality of layers including an inorganic insulating material and/or an organic insulating material.

The upper hole TH and the drain hole DH can be disposed in the interlayer insulating layer 160. Accordingly, a portion of the upper surface of the first connection part 132a of the active layer 130 can be exposed by the upper hole TH, and the lower hole BH of the active layer 130 can be exposed by the upper hole TH. Furthermore, a portion of the upper surface of the second connection part 132b of the active layer 130 can be exposed by the drain hole DH.

The source electrode 170 and the drain electrode 180 can be disposed on the interlayer insulating layer 160. The source electrode 170 and the drain electrode 180 can be formed of the same material as the gate electrode 150, but are not limited thereto and can be formed of a material according to knowledge of the art.

The source electrode 170 can be electrically connected to one side of the active layer 130, e.g., the first connection part 132a, and the drain electrode 180 can be electrically connected to another side of the active layer 130, e.g., the second connection part 132b. Specifically, the source electrode 170 can be connected to the first connection part 132a of the active layer 130 through the upper hole TH disposed in the gate insulating layer 140 and the interlayer insulating layer 160, and the drain electrode 180 can be connected to the second connection part 132b of the active layer 130 through the drain hole DH disposed in the gate insulating layer 140 and the interlayer insulating layer 160.

According to an embodiment of the present disclosure, the source electrode 170 can be electrically connected to the first connection part 132a of the active layer 130 and the light blocking layer 110 through the upper hole TH disposed in the gate insulating layer 140 and the interlayer insulating layer 160, and the lower hole BH disposed in the buffer layer 120 and the first connection part 132a of the active layer 130, which will be described in detail below through the relationship between the upper hole TH, the lower hole BH, and the source electrode 170 disposed in the upper hole TH and the lower hole BH.

As described above, the upper hole TH can be formed by etching a portion of the gate insulating layer 140 and the interlayer insulating layer 160 from the upper surface of the active layer 130, specifically, the first connection part 132a, and the lower hole BH can be formed by etching a portion of the buffer layer 120 and the first connection part 132a of the active layer 130 from the upper surface of the light blocking layer 110.

The upper hole TH can overlap with the lower hole BH and the two holes can be connected or in communication with each other. Specifically, the entire lower hole BH can overlap with the upper hole TH. Furthermore, the upper hole TH and the lower hole BH can be continuously formed and connected to each other. Accordingly, a portion of the upper surface of the light blocking layer 110 can be exposed by the upper hole TH and the lower hole BH.

The upper hole TH and the lower hole BH can be formed to have different sized areas, and in this situation, the upper hole TH can be formed larger than the lower hole BH. Specifically, the lower area of the upper hole TH can be formed larger than the upper area of the lower hole BH. By forming in this way, the upper hole TH can expose a portion of the upper surface of the first connection part 132a. Specifically, a portion of the upper surface of the first connection part 132a overlapping with the upper hole TH without overlapping the lower hole BH can be exposed by the upper hole TH.

According to an embodiment of the present disclosure, since the upper hole TH and the lower hole BH are continuously formed and connected to each other, the source electrode 170 can be electrically connected to the first connection part 132a through the upper hole TH and can be electrically connected to the light blocking layer 110 through the lower hole BH. Therefore, the light blocking layer 110 and the first connection part 132a can be electrically connected through the upper hole TH and the lower hole BH.

According to a configuration of the present disclosure, since the source electrode 170 penetrates through a portion of the active layer 130 through the upper hole TH and the lower hole BH to be electrically connected to the light blocking layer 110 and the active layer 130, the entire area of the thin film transistor substrate according to the present disclosure can be reduced, the amount of wiring can be reduced, the footprint can be made smaller, and more components can be packed closer together, in order to better facilitate implementation of higher resolutions. If to electrically connect the source electrode, the active layer, and the light blocking layer without the upper hole TH and the lower hole BH, the entire area of the thin film transistor substrate can become larger by the area in which the connection electrode is formed.

The source electrode 170 can include an upper electrode 171 and a lower electrode 172. In this situation, the upper electrode 171 can be defined as a portion of the source electrode 170 disposed in the upper hole TH and on the interlayer insulating layer 160, and the lower electrode 172 can be defined as a portion of the source electrode 170 disposed in the lower hole BH. Accordingly, the upper electrode 171 can be defined as a portion of the source electrode 170 disposed in the gate insulating layer 140 and the interlayer insulating layer 160 and disposed on the interlayer insulating layer 160 from the top surface of the active layer 130. The lower electrode 172 can be defined as a portion of the source electrode 170 disposed in the buffer layer 120 and in the first connection part 132a from the top surface of the light blocking layer 110.

According to an embodiment of the present disclosure, since the size of the upper hole TH is larger than the size of the lower hole BH, the size of the upper electrode 171 can be larger than the size of the lower electrode 172. Specifically, the lower area of the upper electrode 171 can be larger than the upper area of the lower electrode 172.

Since the lower area of the upper electrode 171 is larger than the upper area of the lower electrode 172, the entire lower electrode 172 can be overlapped by the upper electrode 171 in a plane view. Furthermore, the upper electrode 171 can be in contact with the lower electrode 172 and can be in contact with a portion of the upper surface of the first connection part 132a of the active layer 130.

Since the lower electrode 172 can be disposed in the lower hole BH, the lower electrode 172 can be in contact with the inside of the first connection part 132a of the active layer 130. In this situation, the inside of the first connection part 132a can be defined as an area of the first connection part 132a exposed by the lower hole BH. Also, as shown in FIG. 2B, the lower hole BH can be evenly centered underneath and aligned with a center of the upper hole TH, but embodiments are not limited thereto.

Since the upper electrode 171 is in contact with a portion of the upper surface of the first connection part 132a and the lower electrode 172 is in contact with the inside of the first connection part 132a, an area in contact between the source electrode 170 and the active layer 130, specifically, the first connection part 132a, can increase, and thus contact resistance between the active layer 130 and the source electrode 170 can decrease (e.g., better electrically contact can be made between the active layer 130 and the source electrode 170, since the source electrode 170 can penetrate all the way through the active layer 130). In this situation, an on-current can increase when the thin film transistor substrate according to an embodiment of the present disclosure is driven by decreasing the contact resistance between the active layer 130 and the source electrode 170 and the brightness of a corresponding subpixel can be improved while reducing power consumption.

FIG. 2B is a cross-sectional view of a thin film transistor substrate according to another embodiment of the present disclosure. In this situation, the cross-sectional view of FIG. 2B corresponds to the cross-section taken along line I-I′ of FIG. 1. Meanwhile, since the thin film transistor substrate of FIG. 2B is the same as the thin film transistor substrate of FIG. 2A except for configurations of the gate insulating layer and the interlayer insulating layer (e.g., the gate insulating layer can have an island shape), different configurations will be mainly described below.

As shown in FIG. 2B, the gate insulating layer 140 may not be disposed on the entire surface of the substrate 100 but can be patterned to coincide with one end and another end of the gate electrode 150. Specifically, one end of the gate insulating layer 140, e.g., a right end can coincide with one end of the gate electrode 150, and another end of the gate insulating layer 140, e.g., a left end, can coincide with another end of the gate electrode 150.

As the gate insulating layer 140 is formed as described above, the upper hole TH and the drain hole DH may not be disposed in the gate insulating layer 140, but can be disposed only in the interlayer insulating layer 160.

The interlayer insulating layer 160 can be disposed on the active layer 130 and the gate electrode 150 and can be in contact with a portion of an upper surface of the active layer 130. As a result, the active layer 130 and the gate electrode 150 can be surrounded by the buffer layer 120 and the interlayer insulating layer 160.

Meanwhile, the configuration of the gate insulating layer and the interlayer insulating layer according to FIG. 2B can be applied to a thin film transistor substrate according to another embodiment described later.

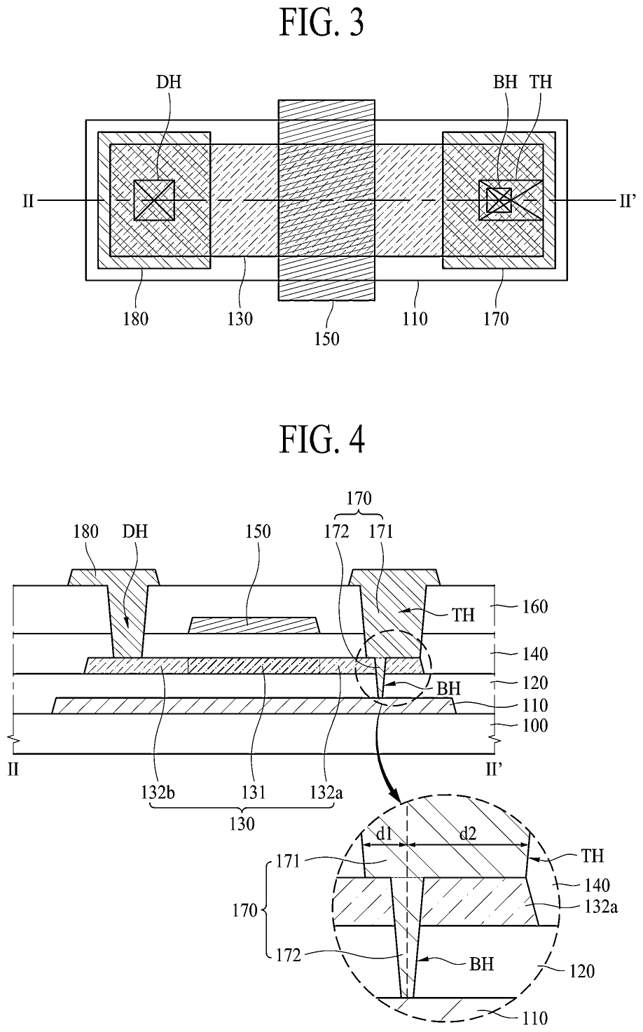

FIG. 3 is a plan view of a thin film transistor substrate according to another embodiment of the present disclosure. Meanwhile, since the thin film transistor substrate according to FIG. 3 is the same as the thin film transistor substrate according to FIG. 1 except for the configuration of the upper hole TH (e.g., the upper hole TH according to FIG. 3 can be made larger than the upper hole TH according to FIG. 1), different configurations will be mainly described below.

As shown in FIG. 3, the thin film transistor substrate according to another embodiment of the present disclosure can include a light blocking layer 110, an active layer 130, a gate electrode 150, a source electrode 170, and a drain electrode 180.

One end of the active layer 130 can be electrically connected to the source electrode 170 through the upper hole TH, and the one end of the active layer 130 can be electrically connected to the light blocking layer 110 through the lower hole BH. In this situation, since the upper hole TH and the lower hole BH overlap with each other, the light blocking layer 110, the active layer 130, and the source electrode 170 can be electrically connected.

According to another embodiment of the present disclosure, one side of the upper hole TH, e.g., the right end side, can coincide with one side of the active layer 130, e.g., the right end side. In other words, an end portion of the upper hole TH can be flush aligned with an end portion of the active layer 130, and an end portion of the source electrode 170 can be flush aligned with an end portion of the active layer 130 to further increase the electrical contact. By forming in this way, the contact area between the source electrode 170 and the active layer 130 formed in the upper hole TH increases, so that the contact resistance between the active layer 130 and the source electrode 170 can be even further lowered. Meanwhile, in FIG. 3, only an embodiment in which one side of the upper hole TH coincides with one side of the active layer 130 is shown, but the present disclosure is not limited thereto. Also, a similar configuration can be applied to the drain electrode 180.

FIG. 4 is a cross-sectional view of a thin film transistor substrate according to another embodiment of the present disclosure. In this situation, the cross-sectional view of FIG. 4 corresponds to the cross-section of II-II′ of FIG. 3. Meanwhile, since the thin film transistor substrate of FIG. 4 is the same as the thin film transistor substrate of FIG. 2A except for the configuration of the upper hole and the upper electrode, different configurations will be mainly described below.

As shown in FIG. 4, a thin film transistor substrate according to another embodiment of the present disclosure can include a substrate 100, a light blocking layer 110, a buffer layer 120, an active layer 130, a gate insulating layer 140, a gate electrode 150, an interlayer insulating layer 160, a source electrode 170, and a drain electrode 180.

According to another embodiment of the present disclosure, the upper hole TH can be asymmetrically formed with respect to the center of the lower hole BH while the upper hole TH overlaps with the lower hole BH (e.g., the center of the lower hole BH can be offset from the center of the upper hole TH). Specifically, while the upper hole TH overlaps with the lower hole BH, one end of the lower surface of the upper hole TH, e.g., a right end can coincide with one end of the first connection part 132a. By forming as described above, one end of the upper electrode 171 disposed in the upper hole TH, e.g., a right end can coincide with one end of the active layer 130. More specifically, the right end of the lower surface of the upper electrode 171 can coincide with the right end of the upper surface of the active layer 130. Meanwhile, only one end of the upper electrode 171 coincides with one end of the active layer 130 in the drawing, but is not limited thereto.

Since the upper hole TH is asymmetrically formed with respect to the center of the lower hole BH, a distance from one end of the upper electrode 171, e.g., a right end to the lower hole BH, can be different than a distance from another end of the upper electrode 171, e.g., a left end to the lower hole BH, which will be described with reference to the enlarged view of FIG. 4.

As can be seen from the enlarged view of FIG. 4, the distance from the one end of the upper electrode 171 to the lower hole BH can be defined as a second distance d2, and the distance from the another end of the upper electrode 171 to the lower hole BH can be defined as a first distance d1. In brief, the first distance d1 and the second distance d2 can be defined as a distance from the center of the lower hole BH to the one end of the upper electrode 171 or the another end of the upper electrode 171, respectively. In this situation, the first distance d1 can be smaller than the second distance d2 (e.g., d1<d2), but embodiments are not limited thereto. Also, the first distance d1 can be greater than the second distance d2.

While one end of the upper electrode 171 coincides with one end of the active layer 130, one end of the drain electrode 180, e.g., a left end, may not coincide with the other end of the active layer 130. In this situation, the size of the upper hole TH disposed with the upper electrode 171 can be larger than the size of the drain hole DH in which the drain electrode 180 is disposed.

According to another embodiment of the present disclosure, as one end of the upper electrode 171 and one end of the active layer 130 coincide with each other, a contact area between the upper electrode 171 and the active layer 130 can increase, and a contact resistance between the active layer 130 and the source electrode 170 of the thin film transistor substrate according to another embodiment of the present disclosure can be even further reduced, and the brightness and response time of the corresponding subpixel can be further improved.

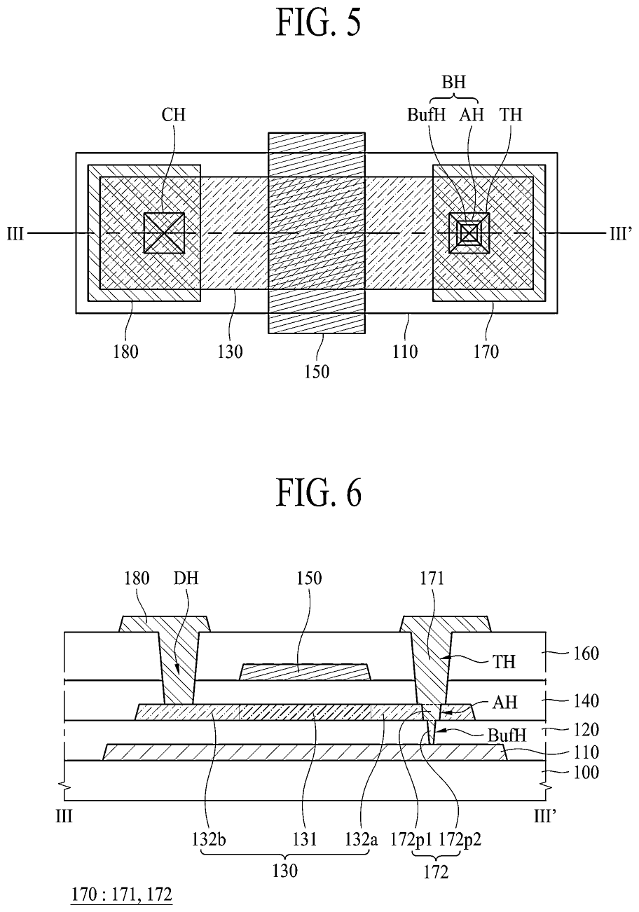

FIG. 5 is a plan view of a thin film transistor substrate according to another embodiment of the present disclosure. Meanwhile, since the thin film transistor substrate according to FIG. 5 is the same as the thin film transistor substrate according to FIG. 1 except for the configuration of the lower hole, different configurations will be mainly described below.

As shown in FIG. 5, a thin film transistor substrate according to another embodiment of the present disclosure can include a light blocking layer 110, an active layer 130, a gate electrode 150, a source electrode 170, and a drain electrode 180.

An upper hole TH and a lower hole BH are disposed on one side of the active layer 130, one side of the active layer 130 and the source electrode 170 can be electrically connected through the upper hole TH, and one side of the active layer 130 and the light blocking layer 110 can be electrically connected through the lower hole BH. In this situation, since the upper hole TH and the lower hole BH overlap with each other, the light blocking layer 110, the active layer 130, and the source electrode 170 can be electrically connected.

According to another embodiment of the present disclosure, the lower hole BH can include an active hole AH and a buffer hole BufH. In this situation, the active hole AH, the buffer hole BufH, and the upper hole TH can overlap each with other. Also, the upper hole TH can be larger than the active hole AH, and the active hole AH can be larger than the buffer hole BufH (e.g., TH>AH>BufH), but embodiments are not limited thereto. Also, the centers of the upper hole TH, the active hole AH and the buffer hole BufH can all be aligned with each other and overlap, but embodiments are not limited thereto.

FIG. 6 is a cross-sectional view of a thin film transistor substrate according to another embodiment of the present disclosure. In this situation, the cross-sectional view of FIG. 6 corresponds to the cross-section taken along line III-III′ of FIG. 5. Meanwhile, since the thin film transistor substrate according to FIG. 6 is the same as the thin film transistor substrate according to FIG. 2A except for the configuration of the lower hole and the lower electrode, different configurations will be mainly described below.

As shown in FIG. 6, a thin film transistor substrate according to another embodiment of the present disclosure can include a substrate 100, a light blocking layer 110, a buffer layer 120, an active layer 130, a gate insulating layer 140, a gate electrode 150, an interlayer insulating layer 160, a source electrode 170, and a drain electrode 180.

According to another embodiment of the present disclosure, the lower hole BH can include an active hole AH and a buffer hole BufH, and the lower electrode 172 can include a first portion 172p1 and a second portion 172p2.

The buffer hole BufH can be defined as an area formed by etching a portion of the buffer layer 120 from the upper surface of the light blocking layer 110, and the active hole AH can be defined as an area formed by etching a portion of the active layer 130 from the upper surface of the buffer layer 120. The buffer hole BufH can overlap with the active hole AH, and the size of the buffer hole BufH can be formed to be smaller than the size of the active hole AH.

Specifically, an area of an upper surface of the buffer hole BufH can be smaller than an area of a lower surface of the active hole AH.

The first portion 172p1 of the lower electrode 172 can be defined as a portion of the source electrode 170 disposed in the active hole AH, and the second portion 172p2 of the lower electrode 172 can be defined as a portion of the source electrode 170 disposed in the buffer hole BufH. In this situation, a size of the first portion 172p1 can be greater than a size of the second portion 172p2 (e.g., 172p1>172p2). Thus, a portion of a lower surface of the first portion 172p1 can be in contact with a portion of the buffer layer 120 exposed by the active hole AH.

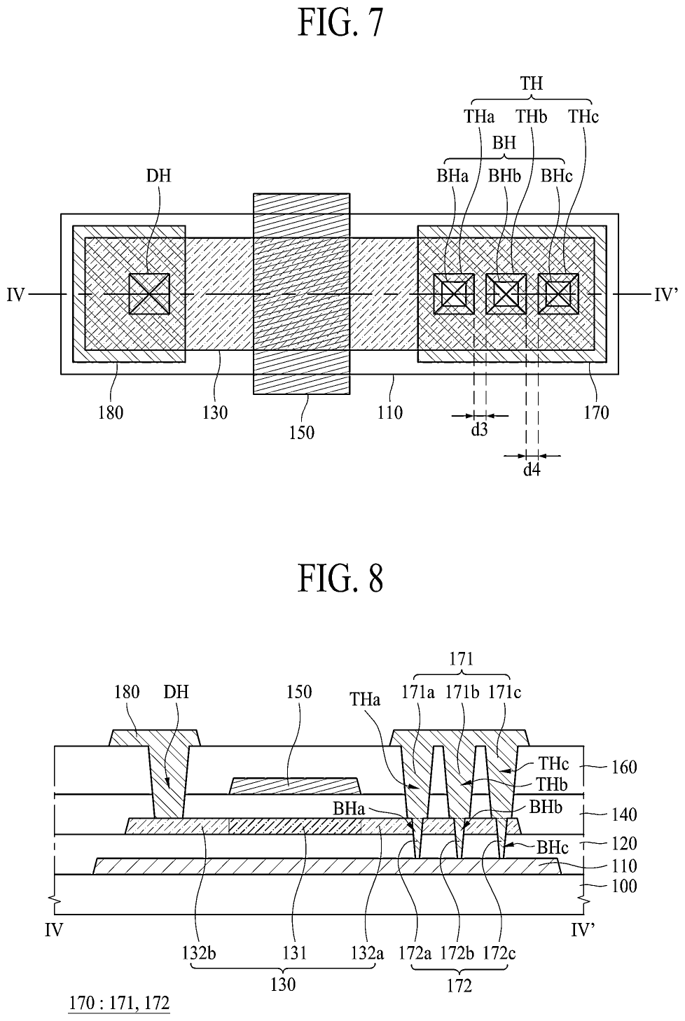

FIG. 7 is a plan view of a thin film transistor substrate according to another embodiment of the present disclosure. Meanwhile, since the thin film transistor substrate according to FIG. 7 is the same as the thin film transistor substrate according to FIG. 1 except for configurations of upper and lower holes (e.g., three through holes can be provided), different configurations will be mainly described below.

As shown in FIG. 7, the thin film transistor substrate according to another embodiment of the present disclosure can include a light blocking layer 110, an active layer 130, a gate electrode 150, a source electrode 170, and a drain electrode 180.

According to another embodiment of the present disclosure, one side of the active layer 130 can be electrically connected to the source electrode 170 and the light blocking layer 110 through a plurality of upper holes TH and a plurality of lower holes BH. Specifically, one side of the active layer 130 can be electrically connected to the source electrode 170 through the first upper hole THa, the second upper hole THb, and the third upper hole THc, and one side of the active layer 130 can be electrically connected to the light blocking layer 110 through the first lower hole BHa, the second lower hole BHb, and the third lower hole BHc.

By forming as described above, the contact area between the active layer 130 and the source electrode 170 can be increased, and thus the contact resistance between the active layer 130 and the source electrode 170 can be reduced.

The first upper hole THa and the second upper hole THb can be spaced apart from each other with a third distance d3 therebetween, and the second upper hole THb and the third upper hole THc can be spaced apart from each other with a fourth distance d4 therebetween. In this situation, the third distance d3 and the fourth distance d4 can be the same as or different from each other.

On the other hand, although FIG. 7 shows the plurality of upper holes TH and the plurality of lower holes BH arranged in a line in a first direction, e.g., a horizontal direction, the plurality of upper holes TH and the plurality of lower holes BH can be arranged in a line in a second direction orthogonal to the first direction, e.g., in a vertical direction, and n upper holes TH and lower holes BH in the first direction and m upper holes TH and lower holes BH in the second direction can be arranged in a number of n×m. Further, the plurality of upper holes TH and the plurality of lower holes BH can be arranged in a multidimensional array, matrix or grid formation (e.g., 2×2, 4×4, 3×2, etc.).

FIG. 8 is a cross-sectional view of a thin film transistor substrate according to another embodiment of the present disclosure. In this situation, the cross-sectional view of FIG. 8 corresponds to the cross-section of IV-IV′ of FIG. 7. Meanwhile, the thin film transistor substrate of FIG. 8 is the same as the thin film transistor substrate of FIG. 2A except for configurations of the upper hole, the lower hole, the upper electrode and the lower electrode, and thus different configurations will be mainly described below.

As shown in FIG. 8, the first connection part 132a of the active layer 130 can be electrically connected to the source electrode 170 through a plurality of upper holes TH, and the first connection part 132a of the active layer 130 can be electrically connected to the light blocking layer 110 by the source electrode 170 disposed in a plurality of lower holes BH.

The plurality of upper holes TH can include a first upper hole THa, a second upper hole THb, and a third upper hole THc, and the plurality of lower holes BH can include a first lower hole Bha, a second lower hole BHb, and a third lower hole BHc.

The plurality of upper holes TH can be formed by etching a portion of the gate insulating layer 140 and a portion of the interlayer insulating layer 160 from the upper surface of the active layer 130, and the plurality of lower holes BH can be formed by etching a portion of the buffer layer 120 and a portion of the active layer 130 from the upper surface of the light blocking layer 110.

The first upper hole Tha can be connected to the first lower hole Bha, the second upper hole THb can be connected to the second lower hole BHb, and the third upper hole THc can be connected to the third lower hole BHc. In other words, each of the plurality of upper holes THs can correspond to the plurality of lower holes BH on a one-to-one basis. However, the present disclosure is not limited thereto, and one upper hole can correspond to a plurality of lower holes (e.g., a one to many relationship), as in an embodiment to be described with reference to FIG. 10. This regard will be described in detail with reference to FIG. 10.

Since the upper hole TH and the lower hole BH are formed in plural, the upper electrode 171 and the lower electrode 172 can also be formed in plural. Meanwhile, in the drawing, for illustration, the upper electrode 171 and the lower electrode 172 are formed in three, respectively, but the present disclosure is not limited thereto.

Specifically, the upper electrode 171 can include a first upper electrode 171a, a second upper electrode 171b, and a third upper electrode 171c, and the lower electrode 172 can include a first lower electrode 172a, a second lower electrode 172b, and a third lower electrode 172c. In this situation, each of the plurality of upper electrodes 171a, 171b, and 171c can be defined as portion of the source electrode 170 disposed in the plurality of upper holes THa, THb, and THc, and can be defined as portion of the source electrode 170 disposed on the interlayer insulating layer 160, and each of the plurality of lower electrodes 172a, 172b, and 172c can be defined as portion of the source electrode 170 disposed in the plurality of lower holes BHa, BHb, and BHc.

According to another embodiment of the present disclosure, since the source electrode 170 includes the plurality of upper electrodes 171a, 171b, and 171c and the plurality of lower electrodes 172a, 172b, and 172c, a contact area between some of the lower surfaces of the plurality of upper electrodes 171a, 171b, and 171c and the first connection part 132a of the active layer 130 can be further increased. Accordingly, since the contact resistance between the active layer 130 and the source electrode 170 is further reduced, when the thin film transistor substrate according to another embodiment of the present disclosure is driven, improved on-current can be obtained and the brightness and response time of a corresponding subpixel can be improved, while maintain a small footprint.

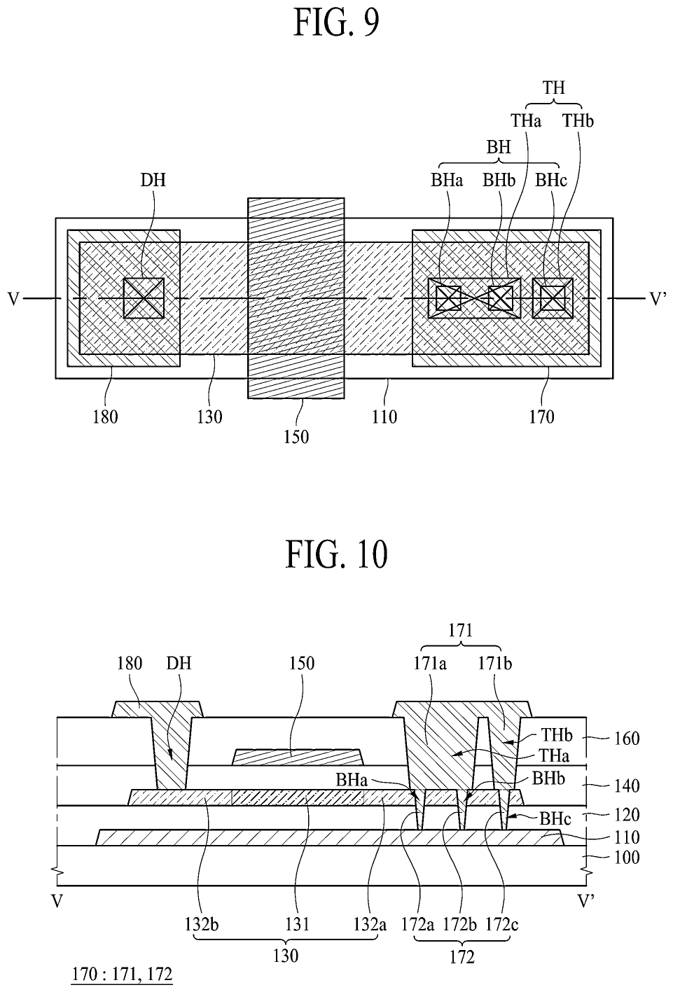

FIG. 9 is a plan view of a thin film transistor substrate according to another embodiment of the present disclosure. Meanwhile, since the thin film transistor substrate according to FIG. 9 is the same as the thin film transistor substrate according to FIG. 7 except for the configuration of the upper hole, different configurations will be mainly described below.

As shown in FIG. 9, the plurality of upper holes TH and the plurality of lower holes BH may not correspond to each other on a one-to-one basis. Specifically, the plurality of upper holes THs can include a first upper hole THa and a second upper hole THb, and the plurality of lower holes BH can include a first lower hole BHa, a second lower hole BHb, and a third lower hole BHc. In this situation, the first upper hole THa can overlap with the first lower hole BHa and the second lower hole BHb, and the second upper hole THb can overlap with the third lower hole BHc.

According to another embodiment of the present disclosure, since the plurality of upper holes TH and the plurality of lower holes BH do not correspond in a one-to-one manner, as in the embodiment of FIG. 7, a contact area between the active layer 130 and the source electrode 170 can be increased as compared with a situation where the plurality of upper holes and the plurality of lower holes overlap in a one-to-one manner. Accordingly, contact resistance between the active layer 130 and the source electrode 170 can be even further reduced.

FIG. 10 is a cross-sectional view of a thin film transistor substrate according to another embodiment of the present disclosure. In this situation, the cross-sectional view of FIG. 10 corresponds to the cross-section of V-V′ of FIG. 9. Meanwhile, since the thin film transistor substrate of FIG. 10 is the same as the thin film transistor substrate of FIG. 8 except for the configuration of the upper hole and the upper electrode, different configurations will be mainly described below.

As shown in FIG. 10, the first connection part 132a of the active layer 130 can be electrically connected to the source electrode 170 through a plurality of upper holes TH, and the first connection part 132a of the active layer 130 can be electrically connected to the light blocking layer 110 by the source electrode 170 disposed in a plurality of lower holes BH.

The plurality of upper holes TH can include a first upper hole THa and a second upper hole THb, and the plurality of lower holes BH can include a first lower hole BHa, a second lower hole BHb, and a third lower hole BHc.

According to another embodiment of the present disclosure, the first upper hole THa can be connected to the first lower hole BHa and the second lower hole BHb, and the second upper hole THb can be connected to the third lower hole BHc. In other words, the plurality of upper holes THs may not correspond to the plurality of lower holes BH on a one-to-one basis (e.g., a one to many relationship can be provided in which one upper hole is in communication with two or more lower holes, etc.).

Since the upper hole TH and the lower hole BH are formed in plural, the upper electrode 171 and the lower electrode 172 can also be formed in plural.

Specifically, the upper electrode 171 can include a first upper electrode 171a and a second upper electrode 171b, and the lower electrode 172 can include a first lower electrode 172a, a second lower electrode 172b, and a third lower electrode 172c.

Since the first upper hole THa is connected to the first lower hole BHa and the second lower hole BHb, the first upper electrode 171a can overlap with the first lower electrode 172a and the second lower electrode 172b and can be electrically connected.

The lower surface of the first upper electrode 171a can be in contact with a portion of the upper surface of the first connection part 132a of the first active layer 130, the upper surface of the first lower electrode 172a, and the upper surface of the second lower electrode 172b. In this situation, the lower surface of the first upper electrode 171a, which is in contact with a portion of the upper surface of the first connection part 132a, can be in contact with the upper surface of the first connection part 132a outside the first lower electrode 172a, e.g., in the left side, can be in contact with the upper surface of the first connection part 132a outside the second lower electrode 172b, e.g. in the right side, and furthermore, can be in contact with a portion of the upper surface of the first connection part 132a between the first lower electrode 172a and the second lower electrode 172b.

In this situation, a portion of the lower surface of the first upper electrode 171a in contact with the first connection part 132a between the first lower electrode 172a and the second lower electrode 172b can be said that the lower surface of the first upper electrode 171a is continuously connected to the adjacent lower electrodes 172a and 172b among the plurality of lower electrodes 172 in contact with a portion of the upper surface of the first connection part. For example, the upper electrode 171 can have a multi-pronged fork structure that penetrates through the active layer 130, which can provide even better electrical contact. Also, first upper electrode 171a and the adjacent lower electrodes 172a and 172b form a type of two pronged fork structure, but embodiments are not limited thereto, and an upper electrode can form a forked structure with three or more lower electrodes.

Since a portion of the lower surface of the first upper electrode 171a contacts a portion of the upper surface of the first connection part 132a between the first lower electrode 172a and the second lower electrode 172b, a contact area between a portion of the upper surface of the first connection part 132a of the active layer 130 and the lower surface of the upper electrode 171 can be increased. Accordingly, according to another embodiment of the present disclosure, since the contact resistance between the active layer 130 and the source electrode 170 is further reduced, when the thin film transistor substrate according to another embodiment of the present disclosure is driven, improved on-current can be obtained while also maintain a small footprint size.

Meanwhile, since the second upper electrode 171b and the third lower electrode 172c are the same as the configurations of the upper electrode and the lower electrode corresponding to each other on a one-to-one basis in FIG. 2A or FIG. 8 described above, a detailed description thereof will be omitted.

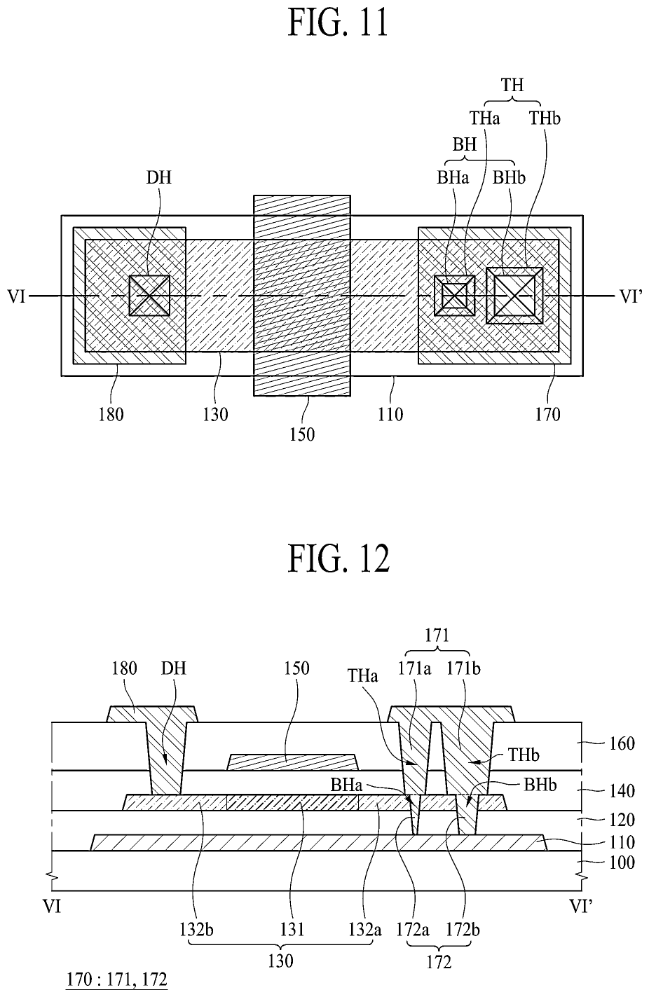

FIG. 11 is a plan view of a thin film transistor substrate according to another embodiment of the present disclosure. Meanwhile, since the thin film transistor substrate according to FIG. 11 is the same as the thin film transistor substrate according to FIG. 1 except for configurations of upper holes and lower holes, different configurations will be mainly described below.

As shown in FIG. 11, a thin film transistor substrate according to another embodiment of the present disclosure can include a light blocking layer 110, an active layer 130, a gate electrode 150, a source electrode 170, and a drain electrode 180.

According to another embodiment of the present disclosure, one side of the active layer 130 can be electrically connected to the source electrode 170 and the light blocking layer 110 through a plurality of upper holes TH and a plurality of lower holes BH. Specifically, one side of the active layer 130 can be electrically connected to the source electrode 170 through a first upper hole THa and a second upper hole THb, and one side of the active layer 130 can be electrically connected to the light blocking layer 110 through a first lower hole Bha and a second lower hole BHb.

By forming as described above, the contact area between the active layer 130 and the source electrode 170 can be increased, and thus the contact resistance between the active layer 130 and the source electrode 170 can be reduced.

According to another embodiment of the present disclosure, the area of each of the plurality of upper holes THs can be different, and the area of each of the plurality of lower holes BH can be different (e.g., the sizes of the upper holes can be different from each other, and the sizes of the lower holes can be different from each other). Specifically, the area of the second upper hole THb can be larger than the area of the first upper hole THa, and the area of the second lower hole BHb can be larger than the area of the first lower hole BHa. By forming in this way, the contact area between the active layer 130 and the source electrode 170 can increase as compared with the situation where the area of each of the plurality of upper holes THs is the same and the area of each of the plurality of lower holes BH is the same. Accordingly, the contact resistance between the active layer 130 and the source electrode 170 can be reduced.

FIG. 12 is a cross-sectional view of a thin film transistor substrate according to another embodiment of the present disclosure. In this situation, the cross-sectional view of FIG. 12 corresponds to the cross-section of VI-VI′ of FIG. 11. Meanwhile, the thin film transistor substrate of FIG. 12 is the same as the thin film transistor substrate of FIG. 2A except for configurations of the upper hole, the lower hole, the upper electrode and the lower electrode, and thus different configurations will be mainly described below.

As shown in FIG. 12, the first connection part 132a of the active layer 130 can be electrically connected to the source electrode 170 through a plurality of upper holes TH, and the first connection part 132a of the active layer 130 can be electrically connected to the light blocking layer 110 by the source electrode 170 disposed in a plurality of lower holes BH.

The plurality of upper holes TH can include a first upper hole THa and a second upper hole THb, and the plurality of lower holes BH can include a first lower hole BHa and a second lower hole BHb.

The plurality of upper holes TH can be formed by etching a portion of the gate insulating layer 140 and a portion of the interlayer insulating layer 160 from the upper surface of the active layer 130, and the plurality of lower holes BH can be formed by etching a portion of the buffer layer 120 and a portion of the active layer 130 from the upper surface of the light blocking layer 110.

The first upper hole THa can be connected to the first lower hole BHa, and the second upper hole THb can be connected to the second lower hole BHb. In other words, each of the plurality of upper holes THs can correspond to the plurality of lower holes BH on a one-to-one basis.

According to another embodiment of the present disclosure, since the contact area between the second upper electrode 171b and a portion of the upper surface of the first connection part 132a of the active layer 130 is larger than the contact area between the first upper electrode 171a and a portion of the upper surface of the first connection part 132a of the active layer 130, the contact area between the active layer 130 and the source electrode 170 can increase, and the contact resistance between the active layer 130 and the source electrode 170 can be reduced. Accordingly, when the thin film transistor substrate according to another embodiment of the present disclosure is driven, improved on-current can be obtained.

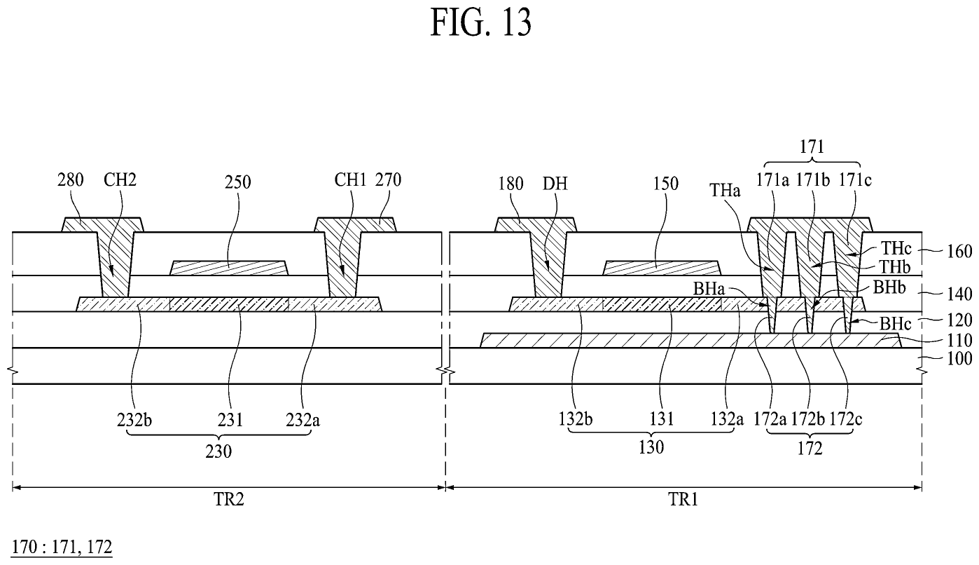

FIG. 13 is a cross-sectional view of a thin film transistor substrate according to another embodiment of the present disclosure.

As shown in FIG. 13, the thin film transistor substrate according to another embodiment of the present disclosure can include the first thin film transistor TR1 and the second thin film transistor TR2.

The display device can include a display area and a non-display area, a plurality of pixels can be disposed in the display area, and a gate driving circuit can be disposed in the non-display area.

Any one of the plurality of pixels includes a plurality of thin film transistors, any one of the plurality of thin film transistors can include a driving thin film transistor for driving pixels, and another thin film transistor among the plurality of thin film transistors can include a switching thin film transistor for transmitting a data signal to the driving thin film transistor. Furthermore, the gate driving circuit can also include a plurality of thin film transistors.

As shown in FIG. 13, the thin film transistor substrate according to another embodiment of the present disclosure can include the first thin film transistor TR1 and the second thin film transistor TR2, the first thin film transistor TR1 can be a driving thin film transistor disposed in any one of the plurality of pixels, and the second thin film transistor TR2 can be any one of a switching thin film transistor disposed in any one of the plurality of pixels or a plurality of thin film transistors disposed in the gate driving circuit.

The first thin film transistor TR1 can include a substrate 100, a first light blocking layer 110, a buffer layer 120, a first active layer 130, a gate insulating layer 140, a first gate electrode 150, an interlayer insulating layer 160, a first source electrode 170, and a first drain electrode 180. Meanwhile, the first light blocking layer 110, the first active layer 130, the first gate electrode 150, the first source electrode 170, and the first drain electrode 180 of the first thin film transistor are the same as those of the thin film transistor substrate according to an embodiment of FIG. 8 above, and thus repeated descriptions thereof will be omitted.

The second thin film transistor TR2 can include a substrate 100, a buffer layer 120, a second active layer 230, a gate insulating layer 140, a second gate electrode 250, an interlayer insulating layer 160, a second source electrode 270, and a second drain electrode 280. Meanwhile, the substrate 100, the buffer layer 120, the gate insulating layer 140, and the interlayer insulating layer 160 are the same as those described in FIG. 8, and thus different configurations will be mainly described below.

The second active layer 230 can be disposed on the buffer layer 120.

The second active layer 230 can include a semiconductor material, e.g., an oxide semiconductor material. The oxide semiconductor material can include at least one of, e.g., an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material.

The second active layer 230 can include a channel part 231, a first connection part 232a connected to one side of the channel part 231, e.g., a right side, and a second connection part 232b connected to another side of the channel part 231, e.g., a left side of the channel part 231. The first connection part 232a and the second connection part 232b can have conductive characteristics by a conducting process in which a semiconductor material is ion-doped or plasma-treated using the second gate electrode 250 as a mask, and the first connection part 232a and the second connection part 232b have better conductivity than the channel part 231, and each can serve as a wiring or source/drain electrode.

The second gate electrode 250 can be disposed on the gate insulating layer 140. The second gate electrode 250 can be disposed on the second active layer 230. Specifically, the second gate electrode 250 can overlap with the channel part 231 of the second active layer 230.

The second gate electrode 250 can include at least one of an aluminum-based metal such as aluminum Al or an aluminum alloy, a silver-based metal such as silver Ag or a silver alloy, a copper-based metal such as copper Cu or a copper alloy, a molybdenum-based metal such as molybdenum Mo or a molybdenum alloy, chromium Cr, tantalum Ta, neodymium Nd, and titanium Ti. The second gate electrode 250 can have a structure including one metal layer or a multilayer structure including at least two metal layers each having different physical properties.

A first contact hole CH1 and a second contact hole CH2 can be disposed in the interlayer insulating layer 160, and accordingly, a portion of the upper surface of the first connection part 232a of the second active layer 230 can be exposed by the first contact hole CH1, and a portion of the upper surface of the second connection part 232b of the second active layer 230 can be exposed by the second contact hole CH2.

The second source electrode 270 and the second drain electrode 280 can be disposed on the interlayer insulating layer 160. The second source electrode 270 and the second drain electrode 280 can be formed of the same material as the second gate electrode, but are not limited thereto and can be formed of a material according to knowledge of the art.

The second source electrode 270 can be electrically connected to the first connection part 232a of the second active layer 230 through the first contact hole CH1, and the second drain electrode 280 can be electrically connected to the second connection part 232b of the second active layer through the second contact hole CH2.

According to another configuration of the present disclosure, when the first thin film transistor TR1 can be any one of the driving thin film transistors disposed in the plurality of pixels and the second thin film transistor TR2 can be any one of the switching thin film transistors disposed in the plurality of pixels or the plurality of thin film transistors disposed in the gate driving circuit, the driving thin film transistor made of the first thin film transistor TR1 can easily express gray scale by a large capacitor, and the switching thin film transistor made of the second thin film transistor TR2 or the thin film transistor disposed in the gate driving circuit can maintain on-current characteristics.

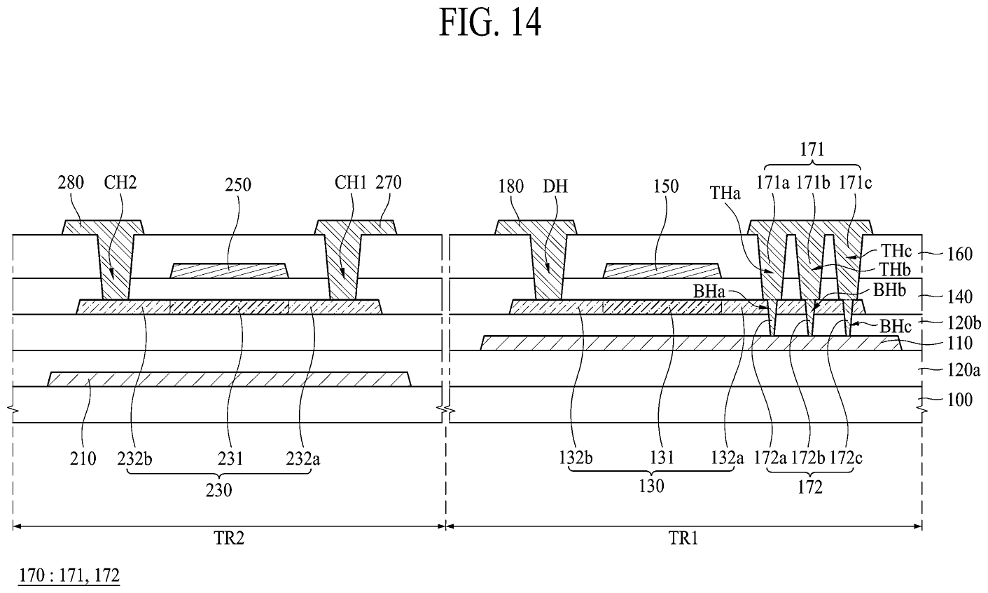

FIG. 14 is a cross-sectional view of a thin film transistor substrate according to another embodiment of the present disclosure. Meanwhile, an embodiment of FIG. 14 is the same as an embodiment of FIG. 13 except that the first buffer layer and the second light blocking layer are disposed in the second thin film transistor, and thus different configurations will be mainly described below.

As shown in FIG. 14, the second thin film transistor TR2 can include a substrate 100, a second light blocking layer 210, a first buffer layer 120a, a second buffer layer 120b, a second active layer 230, a gate insulating layer 140, a second gate electrode 250, an interlayer insulating layer 160, a second source electrode 270, and a second drain electrode 280.

The second light blocking layer 210 can be disposed on the substrate 100. The second light blocking layer 210 can be formed of a metal or a metal oxide, and can be formed of one metal layer or a metal oxide layer, or can be formed of two or more metal layers or metal oxide layers. The second light blocking layer 210 can be formed of a material different from that of the first light blocking layer 110, but is not limited thereto.

The second light blocking layer 210 can be disposed under the second active layer 230 and overlaps with the second active layer 230, thereby preventing light introduced from the outside of the thin film transistor substrate from being introduced into the second active layer 230 and preventing potential damage to the second active layer 230. Specifically, the second light blocking layer 210 can prevent external light from being introduced into the channel part 231 of the second active layer 230. Meanwhile, the second light blocking layer 210 can be electrically connected to the second gate electrode 250. When the second light blocking layer 210 is electrically connected to the second gate electrode 250, the second thin film transistor TR2 can have a double gate structure in which gate electrodes are disposed above and below the second active layer 230 (e.g., the second light blocking layer 210 can be used as one of gate electrodes of a double gate electrode structure).

The first buffer layer 120a can be disposed on the second light blocking layer 210. The first buffer layer 120a can be formed of an inorganic insulating material such as silicon oxide, silicon nitride, or metal oxide, but is not limited thereto and can be formed of an organic insulating material. The first buffer layer 120a can be formed of a single layer or a plurality of layers.

The second buffer layer 120b can be disposed on the first buffer layer 120a and the first light blocking layer 110. The second buffer layer 120b is the same as the configuration of the buffer layers described in FIGS. 2a, 2b, 4, 6, 8, 10 and 12, and thus a detailed description thereof will be omitted.

According to another configuration of the present disclosure, the second thin film transistor TR2 can be any one switching thin film transistor disposed in the plurality of pixels, and in this situation, since the second thin film transistor TR2 has the double gate structure, on-current characteristics can be further increased. As a result, the driving thin film transistor of any one of the plurality of pixels is made of the first thin film transistor TR1, and the switching thin film transistor of any one of the plurality of pixels is made of the second thin film transistor TR2, so that the thin film transistor substrate according to the configuration of the present disclosure can easily express gray scale and improve on-current characteristics.

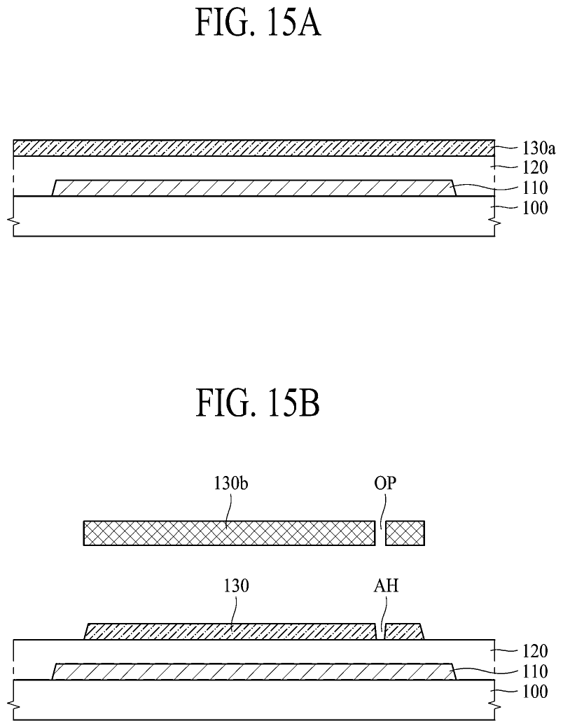

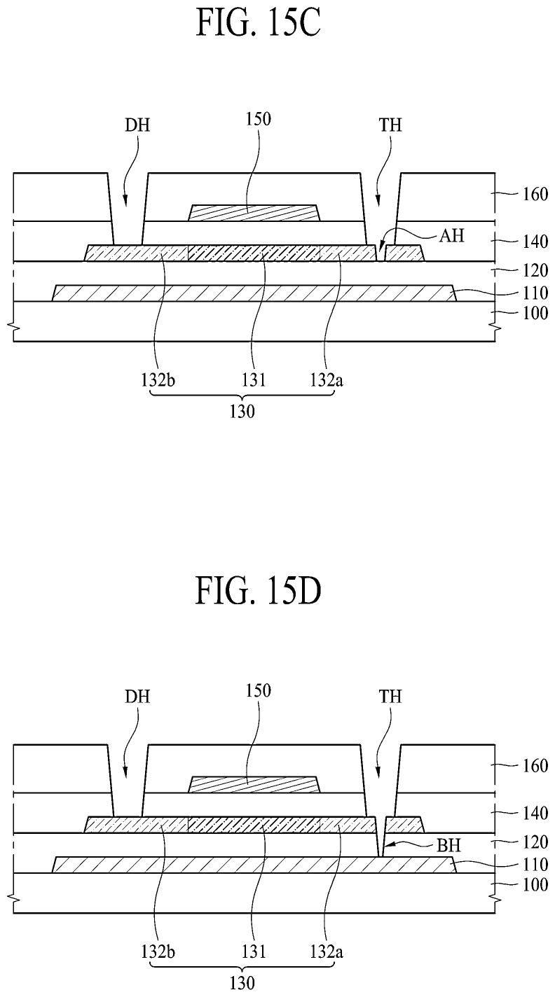

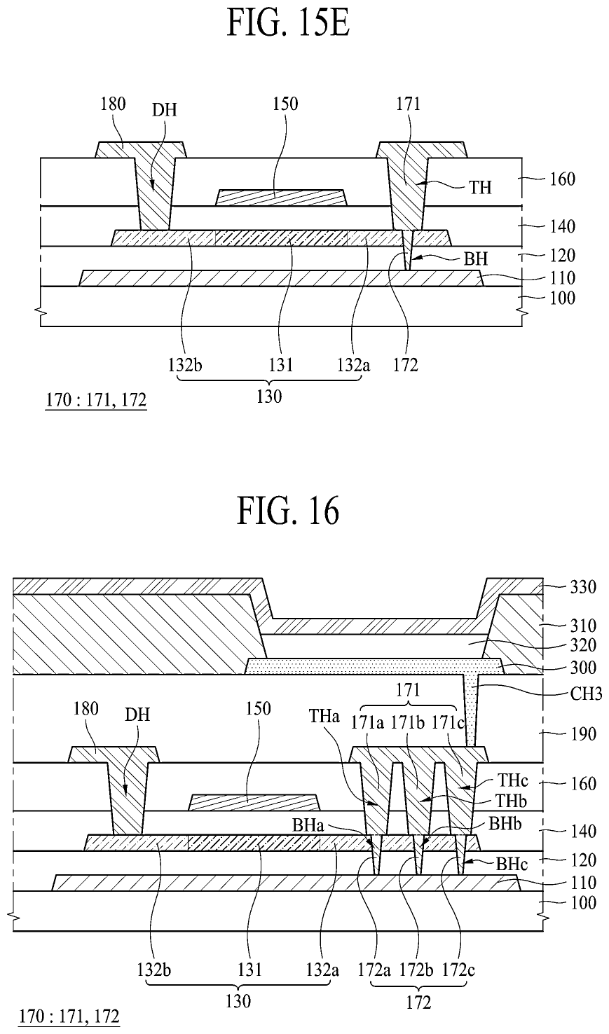

FIGS. 15A to 15E are cross-sectional views illustrating a method of forming a thin film transistor substrate according to an embodiment of the present disclosure.

First, as shown in FIG. 15A, a light blocking layer 110 is formed on the substrate 100, a buffer layer 120 is formed on the light blocking layer 110, and then an oxide semiconductor layer 130a is formed to form an active layer on the buffer layer 120.

Next, as shown in FIG. 15B, the active layer 130 can be formed by patterning the oxide semiconductor layer 130a using the mask 130b. In this situation, the mask 130b is disposed with an opening OP, and when the active layer 130 is patterned, an active hole AH can be formed in a region on the active layer 130 corresponding to the opening OP. The active hole AH can expose an inner region of the active layer 130 to the outside, and can expose a portion of an upper surface of the buffer layer 120 to the outside.

Next, as shown in FIG. 15C, a gate insulating layer 140 can be formed on the active layer 130, a gate electrode 150 can be formed on the gate insulating layer 140, and an interlayer insulating layer 160 can be formed on the gate electrode 150.

Then, after the interlayer insulating layer 160 is formed, the active layer 130 performs a conducting process using the gate electrode 150 as a mask, and thus conductive characteristics can be disposed in a partial region of the active layer 130. Therefore, the active layer 130 can include a channel part 131, a first connection part 132a disposed on one side of the channel part 131, and a second connection part 132b disposed on another side of the channel part 131.

After the conducting process of the active layer 130, an upper hole TH can be formed by etching a portion of the gate insulating layer 140 and a portion of the interlayer insulating layer 160 disposed on the first connection part 132a, and a drain hole DH can be formed by etching a portion of the gate insulating layer 140 and a portion of the interlayer insulating layer 160 disposed on the second connection part 132b. The upper hole TH can expose a portion of the upper surface of the first connection part 132a of the active layer 130, the active hole AH, and a portion of the buffer layer 120 to the outside, and the drain hole DH can expose a portion of the upper surface of the second connection part 132b of the active layer 130 to the outside.

Next, as shown in FIG. 15D, a lower hole BH can be formed by dry etching a portion of the buffer layer 120 exposed by the upper hole TH and the active hole AH. In this situation, by forming the lower hole BH using dry etching, a partial area of the etched buffer layer 120 can be precisely controlled. Specifically, when the lower hole BH is formed using wet etching, the size of the active hole AH of the active layer 130 can be changed, and by using dry etching, a partial area of the buffer layer 120 can be etched while the size of the active hole AH is constantly maintained. Accordingly, different etching techniques can be used for forming the upper hole TH and the lower hole BH (e.g., wet etching, then dry etching).

When the lower hole BH is formed, a partial region of the upper surface of the light blocking layer 110 can be exposed to the outside.

Next, as shown in FIG. 15E, a source electrode 170 can be formed in the upper hole TH and the lower hole BH, and a drain electrode 180 can be formed in the drain hole DH to form a thin film transistor substrate according to an embodiment of the present disclosure.

FIG. 16 is a cross-sectional view of a display device including a thin film transistor substrate according to an embodiment of the present disclosure.

As shown in FIG. 16, the display device according to an embodiment of the present disclosure can include a substrate 100, a light blocking layer 110, a buffer layer 120, an active layer 130, a gate insulating layer 140, a gate electrode 150, an interlayer insulating layer 160, a source electrode 170, a drain electrode 180, a planarization layer 190, a first electrode 300, a bank layer 310, a light emitting layer 320, and a second electrode 330.

The substrate 100, the light blocking layer 110, the buffer layer 120, the active layer 130, the gate insulating layer 140, the gate electrode 150, the interlayer insulating layer 160, the source electrode 170, and the drain electrode 180 are the same as those described above, repeated descriptions thereof will be omitted.

A third contact hole CH3 can be provided on the planarization layer 190 so that the source electrode 170 is exposed by the third contact hole CH3. However, in some situations, the drain electrode 180 can be exposed by the third contact hole CH3.

The first electrode 300 can be formed on the planarization layer 190 and can be connected to the source electrode 170 or the drain electrode 180 through the third contact hole CH3. The first electrode 300 can function as an anode.

The bank layer 310 can be provided to cover an edge of the first electrode 300 to define a light emitting area. Accordingly, an upper surface area of the first electrode 300 exposed without being covered by the bank layer 310 becomes a light emitting area.

The light emitting layer 320 can be provided on the first electrode 300. The light emitting layer 320 can include red, green, and blue light emitting layers patterned for each pixel, or can be formed of a white light emitting layer connected from all pixels. When the light emitting layer 320 is formed of a white emission layer, the light emitting layer 320 can include, e.g., a first stack including a blue emission layer, a second stack including a yellow green emission layer, and a charge generation layer provided between the first stack and the second stack, but is not limited thereto.

The second electrode 330 can be provided on the light emitting layer 320. The second electrode 330 can function as a cathode.

In addition, an encapsulation layer for preventing moisture or oxygen from penetrating can be additionally formed on the second electrode 330.

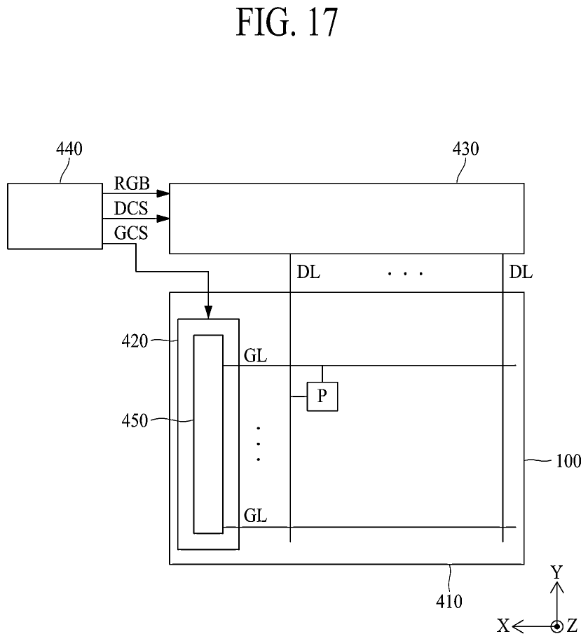

FIG. 17 is a schematic diagram of a display device according to an embodiment of the present disclosure.

As shown in FIG. 17, the display device according to an embodiment of the present disclosure can include a display panel 410, a gate driver 420, a data driver 430, and a controller 440.

The display panel 410 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P can be disposed on the substrate 100.

The controller 440 controls the gate driver 420 and the data driver 430. The controller 440 outputs a gate control signal GCS for controlling the gate driver 420 and a data control signal DCS for controlling the data driver 430 by using a signal supplied from an external system. Also, the controller 440 samples input video data input from the external system and rearranges the sampled input video data, and supplies the rearranged digital video data RGB to the data driver 430.

The gate control signal GCS includes a gate start pulse GSP, a gate shift clock GSC, a gate output enable signal GOE, a start signal Vst, and a gate clock GCLK. Further, control signals for controlling a shift register can be included in the gate control signal GCS.

The data control signal DCS includes a source start pulse SSP, a source shift clock signal SSC, a source output enable signal SOE, and a polarity control signal POL.

The data driver 430 supplies a data voltage to the data lines DL of the display panel 410. Specifically, the data driver 430 converts the video data RGB inputted from the controller 440 into an analog data voltage and supplies the data voltage to the data lines DL.

The gate driver 420 can be mounted on the display panel 410. As described above, a structure in which the gate driver 420 is directly mounted on the display panel 410 is referred to as a gate in panel (GIP) structure. Specifically, in the gate-in-panel (GIP) structure, the gate driver 420 can be disposed on the substrate 100.

The gate driver 420 can include a shift register 450.

The shift register 450 sequentially supplies gate pulses to the gate lines GL during one frame by the use of start signal and gate clock transmitted from the controller 440. Herein, the one frame refers to a period in which one image is outputted through the display panel 410. The gate pulse has a turn-on voltage capable of turning on a switching device (thin film transistor) disposed in the pixel P.

Also, during the remaining period of one frame, in which the gate pulse is not supplied, the shift register 450 supplies a gate-off signal capable of turning off the switching device to the gate line GL. Hereinafter, the gate pulse and the gate-off signal are totally referred to as a gate signal GS.

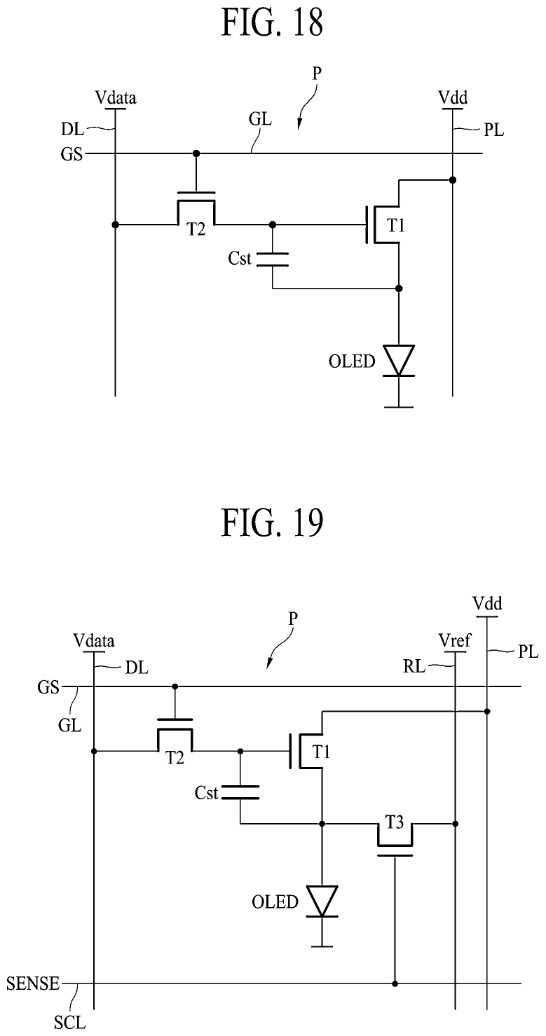

FIG. 18 is a circuit diagram of one pixel provided in a display device according to an embodiment of the present disclosure.

As shown in FIG. 18, the display device according to an embodiment of present disclosure includes first to second thin film transistors T1 and T2 and capacitors Cst.

The first thin film transistor T1 is a driving thin film transistor, and the second thin film transistor T2 is a switching thin film transistor. At least one of the first thin film transistor T1 and the second thin film transistor T2 can be formed of the above-described various thin film transistors.

The first thin film transistor T1 is switched according to the data voltage Vdata supplied from the second thin film transistor T2, generates a data current from the driving voltage Vdd supplied from the power line PL, and supplies the data current to the organic light emitting diode OLED.

The second thin film transistor T2 is switched according to the gate signal GS supplied to the gate line GL and supplies the data voltage Vdata supplied from the data line DL to the first thin film transistor T1.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

FIG. 19 is a circuit diagram of one pixel provided in a display device according to another embodiment of the present disclosure.

As shown in FIG. 19, the display device according to another embodiment of present disclosure includes first to third thin film transistors T1, T2, T3 and a capacitor Cst.

The first thin film transistor T1 is a driving thin film transistor, and the second to third thin film transistors T2 to T3 are switching thin film transistors. At least one of the first to third thin film transistors T1, T2, and T3 can be formed of the above-described various thin film transistors.

The first thin film transistor T1 is switched according to the data voltage Vdata supplied from the second thin film transistor T2, generates a data current from the driving voltage Vdd supplied from the power line PL, and supplies the data current to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

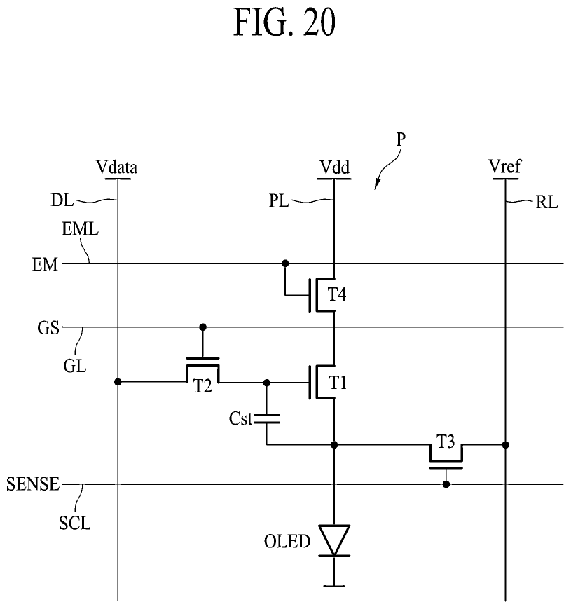

FIG. 20 is a circuit diagram of one pixel provided in a display device according to another embodiment of the present disclosure.

As shown in FIG. 20, the display device according to another embodiment of the present disclosure includes first to fourth thin film transistors T1, T2, T3, and T4 and a capacitor Cst.

The first thin film transistor T1 is a driving thin film transistor, and the second to fourth thin film transistors T2 to T4 are switching thin film transistors. At least one of the first to fourth thin film transistors T1, T2, T3, and T4 can be formed of the above-described various thin film transistors.

The first thin film transistor T1 is switched according to the data voltage Vdata supplied from the second thin film transistor T2, generates a data current from the driving voltage Vdd supplied from the power line PL, and supplies the data current to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The fourth thin film transistor T4 is switched according to the light emission control signal EM supplied to the light emission control line EML and supplies the driving voltage Vdd supplied from the power line PL to the first thin film transistor T1.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

Accordingly, the present disclosure can have the following advantages.

According to an embodiment of the present disclosure, as a lower hole is provided at one side of the active layer and a source electrode is formed to penetrate the lower hole, the active layer, the source electrode, and the light blocking layer disposed under the active layer are connected to each other so that the active layer and the light blocking layer can be electrically connected without a connection electrode.

According to an embodiment of the present disclosure, the active layer and the light blocking layer are electrically connected by the source electrode disposed in the lower hole disposed in one side of the active layer, thereby reducing the size of the thin film transistor and securing an extra space for forming other wirings and electrodes.

According to an embodiment of the present disclosure, since the active layer and the light blocking layer are electrically connected by the source electrode disposed in the lower hole, the S-Factor of the driving thin film transistor can be improved to facilitate gray scale expression.

According to an embodiment of present disclosure, since the lower surface of the upper electrode are in contact with a portion of the upper surface of the active layer, and the lower electrode is in contact with the side surface of the active layer, the contact area between the active layer and the source electrode is increased, thereby reducing contact resistance between the active layer and the source electrode, and brightness of a corresponding subpixel can be improved.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor substrate comprising:
a light blocking layer disposed on a substrate;
an active layer disposed on the light blocking layer, the active layer including a lower hole in one side of the active layer;
a gate electrode disposed on the active layer;
a source electrode electrically connected to both of the active layer and the light blocking layer; and
an insulating layer disposed between the active layer and the source electrode, the insulating layer including an upper hole,
wherein the source electrode includes a lower electrode disposed in the lower hole in the active layer and an upper electrode disposed in the upper hole in the insulating layer,
wherein the active layer and the light blocking layer are electrically connected to each other through the lower electrode, and
wherein an area of a lower surface of the upper electrode is larger than an area of an upper surface of the lower electrode.

2. The thin film transistor substrate according to claim 1, wherein the upper hole and the lower hole are in communication with each other.

3. The thin film transistor substrate according to claim 1, wherein the upper electrode contacts an entire upper surface of the lower electrode and a portion of an upper surface of the active layer.

4. The thin film transistor substrate according to claim 1, wherein a distance from one end of the lower surface of the upper electrode to the lower hole is greater than a distance from another end of the lower surface of the upper electrode to the lower hole, or wherein a center of the upper hole does not overlap with a center of the lower hole.

5. The thin film transistor substrate according to claim 1, further comprising:
a drain hole disposed in the insulating layer; and
a drain electrode disposed on the gate electrode and connected to one side of the active layer through the drain hole,
wherein a size of the upper hole is larger than a size of the drain hole.

6. The thin film transistor substrate according to claim 1, further comprising:
a gate insulating layer disposed between the active layer and the gate electrode,
wherein one end of the gate insulating layer corresponds to one end of the gate electrode, and another end of the gate insulating layer corresponds to another end of the gate electrode, and
wherein the insulating layer includes an interlayer insulating layer that contacts a portion of an upper surface of the active layer.

7. The thin film transistor substrate according to claim 1, wherein the insulating layer includes:
a gate insulating layer disposed between the active layer and the gate electrode and disposed on an entire surface of the substrate; and
an interlayer insulating layer disposed on the gate insulating layer.

8. The thin film transistor substrate according to claim 1, wherein the lower hole includes an active hole and a buffer hole, and
wherein the lower electrode includes:
a first part disposed in the active hole and a second part disposed in the buffer hole; and
an area of a lower surface of the first part is larger than an area of an upper surface of the second part.

9. The thin film transistor substrate according to claim 1, wherein the lower hole and the upper hole do not overlap with the gate electrode.

10. The thin film transistor substrate according to claim 1, wherein the active layer includes a channel part, a first connection part disposed on one side of the channel part, and a second connection part disposed on another side of the channel part, and
wherein the lower electrode is disposed in one of the first connection part and the second connection part.

11. The thin film transistor substrate according to claim 1, wherein the active layer includes at least one of an IZO (InZnO)-based oxide semiconductor material, an IGZO (InGaZnO)-based oxide semiconductor material, an IZTO (InZnSnO)-based oxide semiconductor material, and a ZnO-based oxide semiconductor material.

12. The thin film transistor substrate according to claim 1, wherein the lower electrode includes a plurality of lower electrodes, and
wherein each of the plurality of lower electrodes is spaced apart from each other.

13. The thin film transistor substrate according to claim 12, wherein the upper electrode includes a plurality of upper electrodes, and
wherein the plurality of upper electrodes respectively correspond to the plurality of lower electrodes on a one-to-one basis.

14. The thin film transistor substrate according to claim 12, wherein the upper electrode extends continuously across at least two adjacent lower electrodes among the plurality of lower electrodes.

15. The thin film transistor substrate according to claim 12, wherein the plurality of lower electrodes have different sizes.

16. A method of manufacturing a thin film transistor substrate, the method comprising:
forming a light blocking layer on a substrate;
forming an active layer on the light blocking layer;
forming an active hole in one side of the active layer;
forming a gate insulating layer on the active layer;
forming a gate electrode on the gate insulating layer;
forming an interlayer insulating layer on the gate electrode;
forming an upper hole extending through the gate insulating layer and the interlayer insulating layer;
forming a lower hole exposing a portion of the light blocking layer by extending the active hole; and
forming a source electrode inside the lower hole and inside the upper hole.

17. The method according to claim 16, wherein an area of a lower surface of the upper hole is larger than an area of an upper surface of the lower hole.

18. The method according to claim 16, wherein the forming the active hole in the one side of the active layer includes:
forming a plurality of active holes; and
the forming the lower hole includes forming a plurality of lower holes exposing the light blocking layer by extending the plurality of active holes.

19. The method according to claim 16, further comprising:
forming a drain hole in the gate insulating layer and the interlayer insulating layer,
wherein a size of the drain hole is smaller than a size of the upper hole.

20. A display device comprising:
a display area and non-display area on a substrate;
a first thin film transistor disposed on the substrate; and
a second thin film transistor having a structure different than a structure of the first thin film transistor,
wherein the first thin film transistor includes:
a first light blocking layer;
a first active layer disposed on the first light blocking layer, the first active layer having a lower hole in one side of the first active layer;
a first gate electrode disposed on the first active layer;
a first source electrode electrically connected to both of the first active layer and the first light blocking layer; and
an insulating layer disposed between the first active layer and the first source electrode, the insulating layer having an upper hole,
wherein the first source electrode includes a lower electrode disposed in the lower hole and an upper electrode disposed in the upper hole,
wherein the first active layer and the first light blocking layer are electrically connected to each other through the lower electrode, and
wherein an area of a lower surface of the upper electrode is larger than an area of an upper surface of the lower electrode.

21. The display device according to claim 20, wherein the first thin film transistor is a driving thin film transistor disposed in the display area, and
wherein the second thin film transistor is a switching thin film transistor disposed in the display area or any one thin film transistor disposed in a gate driver disposed in the non-display area.

22. A thin film transistor substrate comprising:
a light blocking layer disposed on a substrate;
an active layer overlapping with the light blocking layer;
a first lower hole penetrating through the active layer;
a gate electrode overlapping with the active layer;
a source electrode penetrating through the active layer and contacting with the light blocking layer;
an insulating layer disposed on the active layer; and
a first upper hole penetrating through the insulating layer,
wherein the source electrode includes a first lower electrode disposed in the first lower hole and a first upper electrode disposed in the first upper hole, and
wherein a width of the first upper electrode is greater than a width of the first lower electrode.

23. The thin film transistor substrate according to claim 22, wherein a center of the first upper hole is aligned with a center of the first lower hole.

24. The thin film transistor substrate according to claim 22, further comprising:
a second lower hole penetrating through the active layer;
a third lower hole penetrating through the active layer; and
a second upper hole penetrating through the insulating layer,
wherein the source electrode is disposed in the first, second and third lower holes and the first and second upper holes.

25. The thin film transistor substrate according to claim 24, further comprising:
a third upper hole penetrating through the insulating layer,
wherein the source electrode is disposed in the first, second and third lower holes and the first, second and third upper holes.

26. The thin film transistor substrate according to claim 24, wherein the first upper hole is in communication with both of the first lower hole and the second lower hole.

27. The thin film transistor substrate according to claim 22, further comprising:
a second lower hole penetrating through the active layer; and
a second upper hole penetrating through the insulating layer,
wherein the source electrode is disposed in the first and second lower holes and the first and second upper holes.
